(19) United States
(12) Patent Application Publication
(10) Pub. No.: US 2004/0178517 A9
(43) Pub. Date: Sep. 16, 2004

(54) Split body peltier device for cooling and power generation applications

(76) Inventor: Wing Ming Siu, Kowloon City (HK)

Correspondence Address: HEATHER MORIN, Fish & Richardson P.C., 11th Floor, 1425 K Street, N.W., Washington, DC, 20005-3500, US

(21) Appl. No.: 10/308,154

(22) Filed: Dec. 3, 2002

Related U.S. Application Data
(60) Provisional application No. 60/341,813, filed on Dec. 21, 2001.

(51) Int. Cl. H01L 23/38; H01L 35/00

(52) U.S. Cl. 257/930

(57) ABSTRACT

A split-body Peltier device includes a plurality of thermoelectric junctions having dissimilar metallic conductors that are functionally interconnected in series and/or parallel by metallic conductors that may be identical to the junction materials. By using these metallic conductors, interconnection electrical resistance is reduced to allow a significant separation between the hot junction and the cold junction without dramatically increasing the ohmic heating. Further, the relatively small area-to-length ratio of the interconnecting material promotes heat loss along its length that effectively prevents heat at the hot junction from reaching the cold junction through the interconnecting material via conduction, thereby substantially eliminating Thermal Back Diffusion and accommodating auxiliary cooling devices to improve the device performance.

### CROSS-REFERENCE TO RELATED APPLICATIONS

This application is an application of and claims priority to U.S. Provisional Application Serial No. 60/341,813, filed on Dec. 21, 2001, titled “A SPLIT BODY PELTIER DEVICE FOR COOLING AND POWER GENERATION APPLICATIONS”.

### TECHNICAL FIELD

This invention relates to thermoelectric conversion devices used in a wide variety of applications, including cooling and power generation.

### BACKGROUND

A Peltier device is a reversible thermoelectric conversion device that utilizes the Peltier effect. The Peltier effect is the heating of one junction and the cooling of an associated second junction when an electric current is maintained in junctions having two dissimilar conductors. That is, when the electric current passes through a junction of two dissimilar materials, heat is either absorbed or released depending on the direction of the electric current through the junction. Since an electric current must be closed in order to ensure a continuous current, in any closed circuit, both cooling (cold) and heating (hot) junctions exist. Thus, the presence of the electric current merely moves the heat from one place to another, and as such, a Peltier device is really a heat pump that can be used in heating and cooling applications. The Peltier device can also be operated in reverse so that by maintaining a temperature difference between the hot and cold junctions an electric current can be generated.

The Peltier effect is related to the difference of the Peltier coefficients of the two dissimilar materials that from the junction. These are often referred to as the junction materials. In general, the larger the difference in the Peltier coefficients, the larger the Peltier effect, and the better the resulting cooling or power generation performance. However, the Peltier effect is also offset by the ohmic heating due to the flow of electric current through the junction materials (I²R heating) and the heat diffusing from the hot junction back toward the cold junction (Thermal Back Diffusion). This balance between the Peltier effect, the ohmic heating, and the Thermal Back Diffusion is represented by the Figure of Merit (Z), which is used in the industry as a means of evaluating the appropriateness of different materials to form the junction in a Peltier device. Generally, materials with a maximum Z are sought due to their low thermal conductivity and large Peltier coefficients, semiconductors are typically the material of choice for Peltier devices, such as bismuth telluride. Much research on Peltier devices is directed toward developing new semiconductor materials with increased Z. However, when using semiconductors as the junction materials the electric resistance, and thus the ohmic heating, can become very large. Although this ohmic heating can be minimized by using superconductors as the junction materials, the necessary cryogenic cooling is rarely either feasible or practical for most conventional thermoelectric applications. Thus, for junctions made out of semiconductors, the ohmic heating is typically managed by reducing the length-to-area ratio of the junction material, thereby decreasing the separation distance between the hot and cold junctions, which tends to increase the Thermal Back Diffusion effect.

Thermal Back Diffusion limits the performance of the current generation of Peltier devices. For power generation applications, it comprises the temperature difference that can be maintained between the hot and cold junctions, and for cooling applications, it compromises the cooling process at the cold junction. One method of managing the Thermal Back Diffusion effect is to increase the thermal insulation between the hot and cold junctions without significantly increasing the electrical resistance. This is, in fact, one direction being pursued in the development of new Peltier devices, but the rate of these developments has been unable to keep up with the growing demand for improved performance. Another method, particularly for cooling applications, is to minimize the temperature difference across the hot and cold junctions, by increasing the rate and efficiency of the heat removal process at the hot junction. There have been numerous efforts to address this heat removal process at the hot junction. Although there has been a focus on improving heat removal at the hot junction, there has not been a focus on the thermal path between the hot and cold junctions. As a result, the effectiveness of the various techniques disclosed for managing the Thermal Back Diffusion remained dependent on the cooling rate that could be achieved at the hot junction. Without explicitly removing the thermal path, the potential still exists for the heat to back-diffuse from the hot junction toward the cold junction. The difference is that with the more efficient heat-removal at the hot junction, the existing Peltier devices can now cool to a higher level before the onset of thermal back-diffusion. For example, there is a limit to the heat flux that can be removed by force convection, and thus for cooling rate requirements above a certain level, neither the heat pipe nor the fin-fan convective systems would be adequate to prevent Thermal Back Diffusion.

Existing Peltier devices in cooling applications are generally incompatible with cooling augmentation by other devices, such as fin-fan or heat pipe devices. Heat transfer in the existing Peltier cooler is a serial process, that is, the amount of cooling at the cold junction is governed by the Peltier effect. Thus, heat removal at the hot junction minimizes the Thermal Back Diffusion effect, but does not increase the cooling process at the cold junction. Consider, for example, a heat pipe capable of 30 Watts of cooling, which is mounted on the hot-junction side of a Peltier cooler, also, capable of 30 Watts of cooling. In this example, although the heat pipe on the hot-junction side removes heat from the hot junction, the heat pipe does not directly increase the rate of heat removal from the cold junction. As a result, end-users cannot augment the cooling power of an existing Peltier cooling device in order to meet higher cooling requirements. That is, if the state-of-the-art Peltier device is only capable of 30 Watts of cooling, end-users requiring 40 Watts of cooling must utilize another cooling technology altogether.

Also, existing Peltier devices have low reliability during handling because most common junction materials are semiconductors that tend to be brittle and easily damaged during handling, installation or thermal cycling. As a result, the existing Peltier cooling devices are not generally compatible with use in high-volume production, low-cost, high-reliability equipment, such as PCs. Similarly, in power generation applications, the lack of durability and the likelihood of damage to the existing Peltier devices tends to reduce their mean-time-to-failure (MTF) performance, lowers their useful life, and renders them generally unsuitable for mobile applications in rugged terrain. In cooling applications, the implications of failure can be much more serious because the non-functional Peltier device becomes a thermal insulator and tends to trap the heat that it was intended to remove. An attempt to address this issue links some of the junctions in both series and parallel so that a failure at one particular junction would not cause an open circuit and cut off the electric current to all of the remaining junctions.

Other issues, unrelated to those discussed above, have also been addressed. For example, proposals include that junction materials be assembled in a mold form and held together by casting resin, junction modules have a diagonal configuration in order to improve the manufacturing process, mechanically strong, thermally stable, low-resistance contacts to thermoelectric bodies be obtained, anisotropy of the materials provide increased power output and a thinner device, alternate methods to manufacture a Peltier cooling device in order to reduce cost and improve the construction of conductive tabs, a Peltier module having improved moisture resistance, methods to miniaturize the thermoelectric device using microelectronic fabrication processes, and a thermoelectric piece is capable of giving an increased adhesive strength between a diffusion barrier layer and a semiconductor matrix.

### SUMMARY

A split body Peltier device provides a structure and a method and a method for effectively dealing with the Thermal Back Diffusion, cooling augmentation, and reliability issues of existing Peltier devices. The split-body Peltier device includes a plurality of thermoelectric junctions having dissimilar metallic conductors. These junctions are, in turn, functionally interconnected in series and/or parallel by metallic conductors (interconnecting material), that are preferably substantially identical in composition to the junction materials being connected. By using metallic conductors, the interconnection electrical resistance can be reduced to a degree such that a significant distance may separate the hot junction from the cold junction without dramatically increasing the ohmic heating. Further, the small area-to-length ratio enables one to attain fin parameters, hPL²/kA, greater than 5.0. (Where h is the effective heat transfer coefficient, k is the thermal conductivity of the interconnecting material, P, L, and A are, respectively, the perimeter, the length, and the cross-sectional area of the interconnecting material.) The increased fin parameter promotes heat loss along the length of the interconnecting material and effectively prevents heat at the hot junction from reaching the cold junction through the interconnecting material via conduction.

The split body Peltier device effectively removes the performance limitations imposed by the Thermal Back Diffusion effect. As a result, the cold junction can operate relatively independently of the temperature at the hot junction, and as such the cooling capability of this invention is much less constrained by the efficiency of the heat removal device at the hot junction. The split-body Peltier device accommodates cooling augmentation by directly attaching other devices such as heat fins or heat pipes directly to the cold junction. As a result, a fin capable of delivering 20 Watts of cooling can now be added to the cold junction of a 30-Watt split-body device and in so doing increase the cooling capacity to the sum total of the two devices (50 Watts). This device can be combined in a cost effective manner with a variety of existing devices to deliver a large range of cooling performance that had previously been either unavailable or impractical. This is of particular importance in electronic cooling applications, where some of the newest microprocessors have needed to incorporate over-temperature shut-down sequences in order to prevent damage or failure resulting from overheating. Such critical cooling demands remain difficult to satisfy in a desktop computer. The split-body Peltier device provides improved reliability as a result of using metallic conductors to form the cold junction to improve both the fracture resistance and the conductivity even in a power-off state.

The details of one or more implementations are set forth in the accompanying drawings and the description below. Other features and advantages will be apparent from the description and drawings, and from the claims.

### DESCRIPTION OF DRAWINGS

The principles of this invention will now be elucidated upon by reference to the attached figures, in which:

FIG. 1 represents in simplified form, a first embodiment of a basic split-body Peltier device including two thermoelectric junctions with interconnecting conductors formed therebetween from junction materials.

FIG. 2 represents, in simplified form, another embodiment of the split-body Peltier device including a plurality of thermoelectric junctions connected in series.

FIG. 3 represents, in simplified form, yet another embodiment of the split-body Peltier device including a plurality of thermoelectric junctions connected in parallel.

FIG. 4 represents, in simplified form, yet another embodiment of the split-body Peltier device including a plurality of thermoelectric junctions connected in both series and parallel.

FIG. 5 represents, in simplified form, another embodiment of the split-body Peltier device with convective cooling fins functionally disposed onto both the cold-plate and hot-plate.

Like reference symbols in the various drawings indicate like elements.

### DETAILED DESCRIPTION

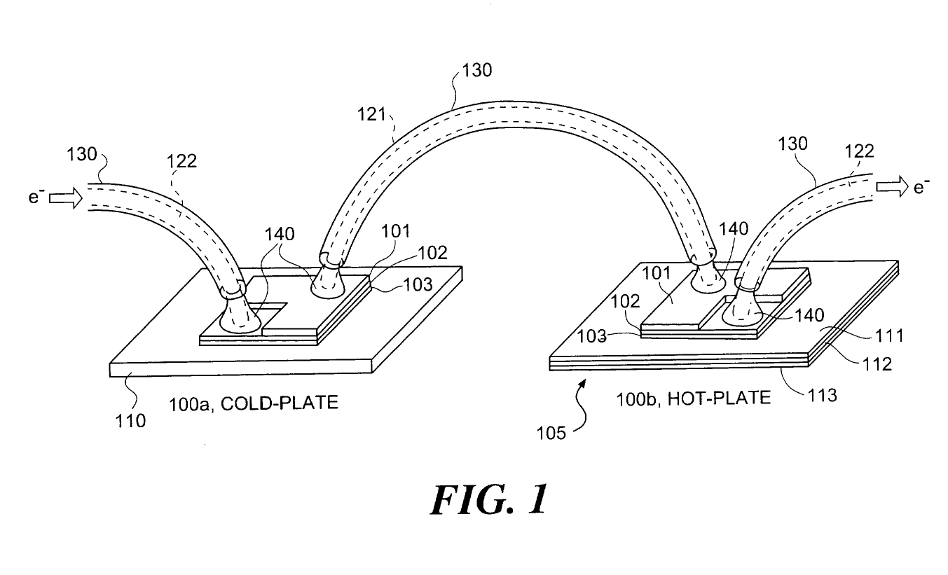

Referring to FIG. 1, a first embodiment of a split-body Peltier device includes a pair of rectangular, conducting junctions 100a, 100b (such that when an electric current is supplied to this circuit, one of the junctions absorbs heat (cold junction) 100a, while the other one 100b releases heat (hot junction).

At first inspection, this embodiment physically resembles a standard thermocouple, there are functional and structural differences. Firstly, a thermocouple is a sensor and it is structured to minimize the transient time-constant and maximize the linearity across the temperature range. However, as a sensor, the thermo-voltage developed across the thermocouple is monitored at high impedance conditions, and the resulting current through the thermocouple is typically negligible so the electrical resistance in a thermocouple is typically very high. For example, a Type-K (Alumel-Chromel) thermocouple constructed from 0.5 mm diameter wires having a total length of 150 mm. The resulting electrical resistance would be in the range of 0.7-0.8 Ω (ohm). Even assuming no Thermal Back Diffusion from the hot junction, Equation 1 below demonstrates that this thermocouple, if operated as a thermoelectric cooler, would have a maximum current of only 9 mA and a maximum cooling capacity of less than 50 uW. Thus, even 1000 thermocouple junctions would only yield 50 mW of cooling, a level of cooling which is simply too low for almost any useful application.

$$\begin{matrix}{Q}_{cold} = {Q}_{Peltier} - {Q}_{ohmic} - {Q}_{back - diffusion} \\ = I ( {α}_{p} - {α}_{n} ) T - ( {I}^{2} {R}_{p} + {I}^{2} {R}_{n} ) - \\ ( {k}_{p} {A}_{p} \frac{ⅆ T}{ⅆ x} + {k}_{n} {A}_{n} \frac{ⅆ T}{ⅆ x} ) \\ {α}_{p} = {α}_{Chromel} = 22.2 μ V / K = 22.2 \times {10}^{- 6} V / k \\ {α}_{n} = {α}_{Alumel} = - 19.6 μ V / K = - 19.6 \times {10}^{- 6} V / k \\ {R}_{p} = \frac{{ρ}_{Chromel} \cdot L}{A} = \frac{70.6 \times {10}^{- 8} \cdot 150 \times {10}^{- 3}}{{( 0.5 \times {10}^{- 3} )}^{2} \cdot π / 4} = 0.54 Ω \\ {R}_{n} = \frac{{ρ}_{Alumel} \cdot L}{A} = \frac{33 \times {10}^{- 8} \cdot 150 \times {10}^{- 3}}{{( 0.5 \times {10}^{- 3} )}^{2} \cdot π / 4} = 0.25 Ω \\ T = 298 K\end{matrix} \qquad Equation ( 1 )$$

Assuming no back diffusion, dT/dx=0

$$\begin{matrix}{Q}_{cold} = I ( 22.2 \times {10}^{- 6} + 19.6 \times {10}^{- 6} ) 298 - {I}^{2} ( 0.54 + 0.25 ) \\ = 0.0125 I - 0.79 {I}^{2}\end{matrix}$$

At optimal Q_{cold}, I=7.88 mA and the Q_{cold,opt}=49×10⁻⁶W=49 uW for one junction.

In the split-body Peltier device, the two junctions are preferably of similar size, approximately 4 mm×4 mm×0.3 mm. Each junction includes a N-type conductor (101) functionally attached to a P-type conductor (102), which is, in turn, functionally attached through a cured adhesive (103) to a thermally conductive substrate (110, 105). The substrate may be a single-piece (110) or a multi-layer piece (100) formed of, for example, a layer of cured polymer (111) such as polymide, functionally attached through pressure or temperature sensitive adhesive (112) to a layer of metal (113). To maximize the Peltier effect, nickel (Ni) or cobalt (Co) is preferred for the N-type conductor, while copper (Cu) is preferred for the P-type conductor. These materials are also preferred for their compatibility with existing plating processes and their relative surface stability. To minimize the electrical resistance, the functional attachment is accomplished through electroplating. In addition, the junction configuration is chosen to further minimize the electrical resistance, to maximize the heat transfer area with the substrate (110), and to minimize the thermal resistance between the cooling interface and the heat transfer area.

Consequently, both the cooling capacity and the thermal conduction process at the cold junction is optimized. Equation 1 above describes the dependence of the cooling capacity at the cold junction on the Peltier effect, ohmic heating, and the thermal back-conduction. Assuming for the moment that this design has no ohmic heating and no Thermal Back Diffusion, the maximum cooling capacity of this junction would simply be the Peltier effect. Thus, as shown in Equation 2, the split-body Peltier device provides a maximum cooling capacity of 30 mW for each Cu—Ni cold junction (49 mW for each Cu—Co cold junction).

### Equation (2)

For Cu—Ni junction at 20° C. with no ohmic heating and assuming a 5 A current:

$$\begin{matrix}{Q}_{cold} = I ( {α}_{Cu} - {α}_{Ni} ) T \\ = 5 ( 1.83 \times {10}^{- 6} + 19.5 \times {10}^{- 20} ) 298 \\ = 0.032 W \\ = 32 mW\end{matrix}$$

For Cu—Co at 20° C. with no ohmic heating and again assuming a 5 A current:

$$\begin{matrix}{Q}_{cold} = I ( {α}_{Cu} - {α}_{Co} ) T \\ = 5 ( 1.83 \times {10}^{- 6} + 30.8 \times {10}^{- 6} ) 298 \\ = 0.049 W \\ = 49 mW\end{matrix}$$

Of course, in reality, some degree of both ohmic heating and Thermal Back Diffusion will exist, so the focus becomes how effectively these two effects are suppressed or otherwise managed by the interconnecting materials. FIG. 1 shows the N-type conductors (101) of both the hot junction and the cold junction interconnected by a conductor (121). Similarly, the P-type conductors (102) of both the hot junction and the cold junction are connected to a conductor (122). In order to avoid forming an additional junction, the conductors (121, 122) are preferably constructed from the same material as the junction conductors (101, 102) to which the conductors are connected or another compatible material that prevents formation of an additional hot-junction near the cold-junction. Further, these interconnectors (121, 122) are electrically insulated from each other with a thermally-conductive polymer coating (130) and, in order to minimize the contact resistance, the interconnectors are functionally attached to their respective junction conductors by, for example, soldering or welding (140).

Metallic conductors are preferred for the interconnecting material because their electrical resistance is sufficiently low to permit the formation of long interconnections that provide much higher fin parameter values (hPL²/kA, where h is the effective heat transfer coefficient, P is the perimeter, L is the length, k is the thermal conductivity and A is the cross-sectional area) than those achieved by the conventional Peltier devices. These higher fin parameter values, for example, 5 or more, indicate that these constructions are capable of minimizing any Thermal Back Diffusion effects by increasing the ability of the interconnecting material (121, 122) to transfer heat away. That is, heat from the hot-junction entering the interconnection is transferred away (e.g., discharged by convection) and prevented from reaching the cold-junction by conduction. With the Thermal Back Diffusion effect under control, the only remaining issue is the ohmic heating. That is, the cooling capacity at the junction becomes a simple balance between the Peltier effect and the ohmic heating. This relationship is represented below in Equation 3. In the split-body Peltier device of (assuming that the interconnectors (121, 122) are 150 mm long and 1.5 mm in diameter interconnectors), the cold junction would be expected to have a minimum cooling capacity of 1.4 mW for a Cu—Ni junction (3.5 mW for a Cu—Co junction). However, through tests conducted on an experimental prototype, ohmic heating is not concentrated at the junctions and that the actual cooling capacity is above the calculated values, with the prototype providing a cooling capacity of more than 2 mW for a Cu—Ni cold-junction (and more than 5 mW for a Cu—Co junction).

$$\begin{matrix}{Q}_{cold} = {Q}_{Peltier} - {Q}_{ohmic} \\ = I ( {α}_{p} - {α}_{n} ) T - ( {I}^{2} {R}_{p} + {I}^{2} {R}_{n} ) \\ {α}_{p} = {α}_{Cu} = 1.83 μ V / K = 1.83 \times {10}^{- 6} V / k \\ {α}_{n} = {α}_{Ni} = - 19.5 μ V / K = - 19.5 \times {10}^{- 6} V / k \\ or {α}_{Co} = - 30.8 μ V / K = - 30.8 \times {10}^{- 6} V / k \\ where {R}_{p} = \frac{{ρ}_{Cu} \cdot L}{A} = \frac{1.673 \cdot {10}^{- 8} \cdot 150 \times {10}^{- 3}}{{( 1.5 \times {10}^{- 3} )}^{2} \cdot π / 4} \\ = 0.0014 ohm \\ {R}_{n} = \frac{{ρ}_{Ni} \cdot L}{A} = \frac{6.84 \times {10}^{- 8} \cdot 150 \times {10}^{- 3}}{{( 1.5 \times {10}^{- 3} )}^{2} \cdot π / 4} \\ = 0.0058 ohm \\ or = \frac{{P}_{Co} \cdot L}{A} = \frac{6.24 \times {10}^{- 8} \cdot 150 \times {10}^{- 3}}{{( 1.5 \times {10}^{- 3} )}^{2} \cdot π / 4} \\ = 0.0053 ohm \\ T = 298 K\end{matrix} \qquad Equation ( 3 )$$

For a Cu—Ni junction with ohmic heating at 20° C.:

$$\begin{matrix}{Q}_{Cold} = I ( 1.83 \times {10}^{- 6} + 19.5 \times {10}^{- 6} ) 298 - {I}^{2} ( 0.0014 + 0.0058 ) \\ = 6.356 \times {10}^{- 3} I - 7.2 \times {10}^{- 3} {I}^{2}\end{matrix}$$

At optimal Q_{Cold}, I=0.44A and the Q_{Cold,opt}=1.4×10⁻W=1.4 mW for one junction.

For a Cu—Co junction with ohmic heating at 20° C.:

$$\begin{matrix}{Q}_{Cold} = I ( 1.83 \times {10}^{- 6} + 30.8 \times {10}^{- 6} ) 298 - {I}^{2} ( 0.0014 + 0.0053 ) \\ = 9.723 \times {10}^{- 3} I - 6.7 \times {10}^{- 3} {I}^{2}\end{matrix}$$

At optimal Q_{cold}, I=0.73 mA and the Q_{cold,opt}=3.5×10⁻³W=3.5mW for one junction

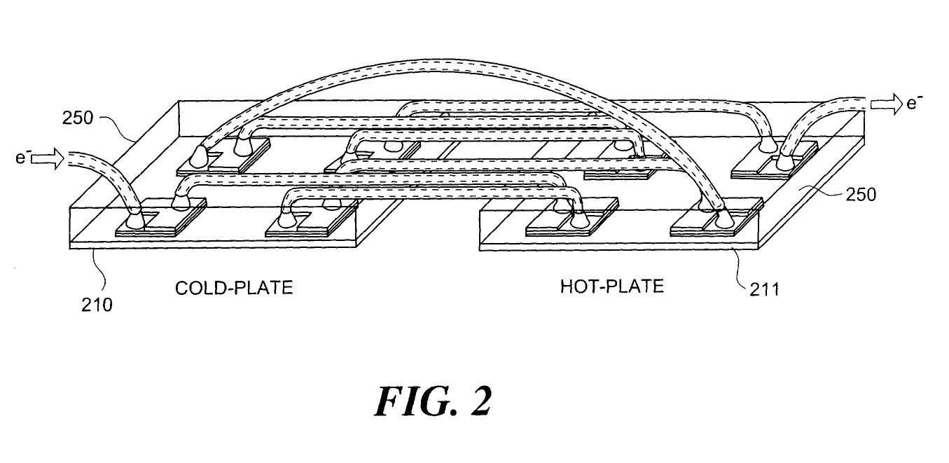

However, because the basic unit is only capable of delivering around 2 mW for each Cu—Ni cold junction, additional junctions are required to deliver additional cooling power. Accordingly, these junctions can be connected in series, parallel, or combination thereof, for example, as shown in FIGS. 2, 3, and 4 and described below.

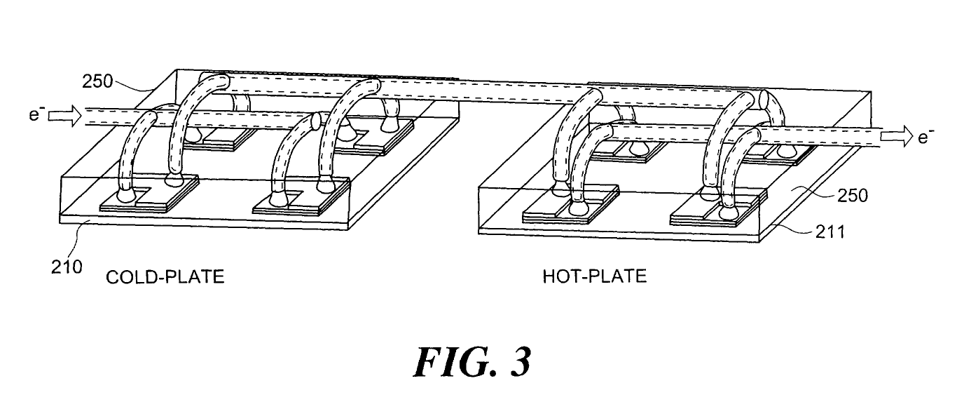

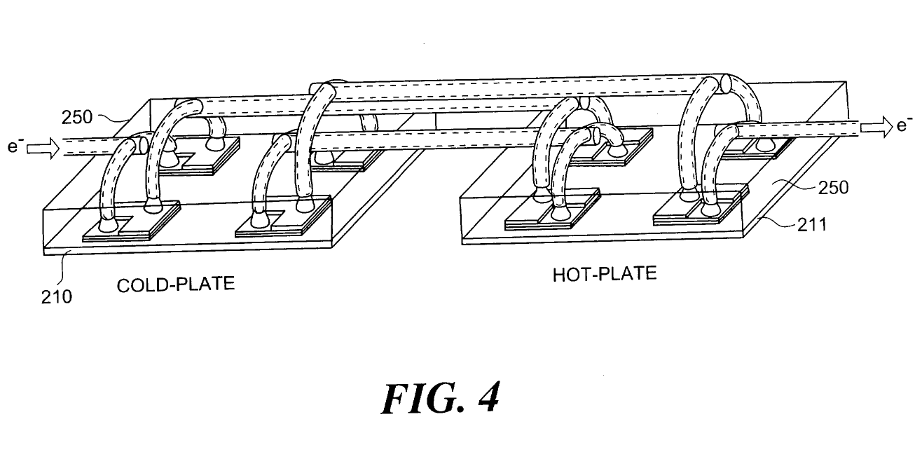

FIG. 2 shows multiple basic units functionally disposed onto substrates so that all the cold-junctions are attached to one substrate (210), while all the hot-junctions are attached to another substrate (211). These substrates serve as a heat transfer medium, and the substrate with the cold junctions is herein called the cold-plate while the other substrate is called the hot plate. As in FIG. 1, the substrates (210, 211) may be a single-layer or a multi-layer construction. The junctions are preferably covered with a cured polymer resin (250) to improve protection and rigidity and are connected in series so that with a thousand cold-junctions, the total cooling power at the cold-plate can be substantially increased to 2 W. The limiting factor in this approach is the number of interconnecting wires required and the associated complexity in the form factor. Alternatively, the basic units are connected in parallel, as shown in FIG. 3, to deliver similar cooling power. The cooling power limiting factor is the amount of current required. That is, if each cold junction requires 0.5A, then 1000 pairs of junctions would require 500 A. Finally, a hybrid approach can be taken whereby the units are connected both in parallel and in series, as shown in FIG. 4, where each series element in the circuit includes a number of junctions connected in parallel. In this way, the complexity of the form factor is minimized and the total current requirement can be maintained at a level that is compatible with most electronic systems.

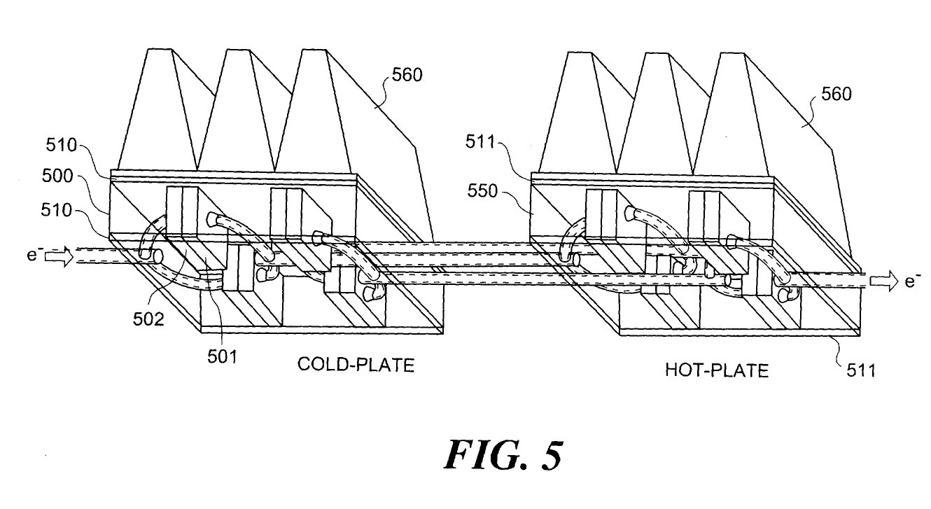

Another implementation of the split-body Peltier device, as shown in FIG. 5, includes the hybrid arrangement of FIG. 4 with the cooling at the cold-plate (210) augmented by additional heat transfer devices such as heat-fins (560 ). The junctions (501, 502) are rotated so that thermally conductive substrates (510, 511) are functionally attached to the top and bottom. A cured polymer resin is preferably disposed between these two substrates for protection purposes. The thermo electric junctions are connected in both series and parallel. In this arrangement, the total cooling capacity at the cold-plate is the sum of the cooling supplied by the Peltier device and the heat-fin attachment (560).

Finally, each implementation, operated in reverse is a power generator, and because a significant distance separates the hot and cold junctions, higher power-generation efficiencies can be achieved. Given below in Equation 4 is the relation for the hybrid implementation with the augmented cooling plate operating as a power generator. Assuming that the cold-plate is exposed to ambient temperature (20° C.) and the hot-plate is exposed to a heat source (120° C.), the calculation shows an expected efficiency of 5.53% with a 1 ohm loading.

Equation (4)

Voltage generation at one junction

V=Tₕₒₜ(α_{Cu,hot}−α_{Ni,hot})−T_{cold}(α_{Cu,cold}−α_{Ni,cold})

where Tₕₒₜ=398K and at this temperature

$$\begin{matrix}{α}_{Cu , cold} = 1.83 μ V / K \\ {α}_{Ni . cold} = - 19.5 μ V / K \\ V = 398 ( 2.33 \times {10}^{- 6} + 22.65 \times {10}^{- 6} ) - 298 ( 1.83 \times {10}^{- 6} + 19.5 \times {10}^{- 6} ) \\ = 9.95 \times {10}^{- 3} - 6.35 \times {10}^{- 3} \\ = 3.6 \times {10}^{- 3} V \\ = 3.6 m V\end{matrix}$$

Assuming that there are 250 elements in series and that each element includes four junctions connected in parallel, the total voltage generated can be calculated as follows:

$$\begin{matrix}{V}_{total} = 250 \times 3.6 m V \\ = 0.9 V\end{matrix}$$

If the total internal resistance is

$$\begin{matrix}{R}_{int} = 250 \times ( \frac{{R}_{Cu} + {R}_{Ni}}{4} ) \\ = 250 \times ( \frac{0.0014 + 0.0058}{4} ) \\ = 0.45 ohm\end{matrix}$$

and a 1 ohm load is applied with the generator,

$$I = \frac{0.9 V}{( 1 + 0.45 ) ohm} = 0.62 A$$

The output power, Wₒᵤₜ, will be

Wₒᵤₜ=I²×R_{load}=(0.62)²×1=0.3844W

The required heat input is Qᵢₙ (assuming only one-tenth of the ohmic heating of the wires will contribute to the heating of the hot plate)

$$\begin{matrix}{Q}_{in} = {Q}_{loss} + {Q}_{peltier} \\ = {Q}_{convection} + {Q}_{back - diffusion} + {Q}_{peltier} \\ = {A}_{surface} h ( {T}_{hot} - {T}_{ambient} ) + {A}_{X - section} ( {k}_{Cu} + {k}_{Ni} ) \frac{{T}_{hot} - {T}_{ambient}}{L} + ( {α}_{Cu , hot} - {α}_{Ni , hot} ) {IT}_{hot}\end{matrix}$$

$$where {A}_{surface} = 4 \times height \times length + {length}^{2} = 4 ( 0.005 ) 0.1 + {0.1}^{2} = 0.012 {m}^{2}$$

$$\begin{matrix}h = 5.5 W / {m}^{2} - K \\ {k}_{Cu} = 401 W / m - K \\ {k}_{Ni} = 90.0 W / m - K \\ {A}_{X - section} = π0 {.15}^{2} / 4 = 1.767 \times {10}^{- 6} {m}^{2} \\ {T}_{ambient} = 298 K\end{matrix}$$

A number of implementations have been described. Nevertheless, it will be understood that various modifications may be made without departing from the spirit and scope of the invention. Accordingly, other implementations are within the scope of the following claims.

What is claimed is:

1. A thermoelectric device, comprising:
a cold junction comprising an N-type conductor in contact with a P-type conductor, the cold junction being in thermal contact with a first conductive substrate;
a hot junction comprising an N-type conductor in contact with a P-type conductor, the hot junction being in thermal contact with a second conductive substrate, the hot junction being substantially thermally isolated from the cold junction;
a primary connector providing electrical contact between the cold junction and the hot junction, wherein the primary connector provides substantially the only thermal contact between the cold junction and the hot junction, the primary connector being arranged and configured to provide a fin parameter of at least 5; and
at least one secondary connector for providing electrical contact between the thermoelectric device and a current source.

2. The thermoelectric device according to claim 1 wherein
the N-type conductor comprises nickel,
the P-type conductor comprises copper,
the primary connector comprises nickel, and
the secondary connector comprises copper.

3. The thermoelectric device according to claim 1 wherein
the N-type conductor comprises cobalt,
the P-type conductor comprises copper,
the primary connector comprises cobalt, and
the secondary connector comprises copper.

4. The thermoelectric device according to claim 2 wherein the cold junction and the hot junction further comprise a base conductor of a first type and a top conductor of a second type, the top conductor having been applied to the base conductor by a plating process to establish contact between the N-type conductor and the P-type conductor.

5. The thermoelectric device according to claim 3 wherein the cold junction and the hot junction further comprise a base conductor of a first type and a top conductor of a second type, the top conductor having been applied to the base conductor by a plating process to establish contact between the N-type conductor and the P-type conductor.

6. The thermoelectric device according to claim 2 wherein the P-type conductor and the N-type conductor comprising a junction are functionally joined to form a junction by a metallurgical process.

7. The thermoelectric device according to claim 6 wherein the metallurgical process comprises welding or soldering.

8. The thermoelectric device according to claim 3 wherein the P-type conductor and the N-type conductor comprising a junction are functionally joined to form a junction by a metallurgical process selected from the group of welding or soldering.

9. The thermoelectric device according to claim 8 wherein the metallurgical process comprises welding or soldering.

10. A thermoelectric device, comprising:
a plurality of cold junctions, each cold junction comprising an N-type conductor in contact with a P-type conductor and each cold junction being in thermal contact with a first conductive substrate;
a plurality of hot junctions, each hot junction comprising an N-type conductor in contact with a P-type conductor and each hot junction being in thermal contact with a second conductive substrate, wherein the number of cold junctions and hot junctions are substantially equal and further wherein the first conductive substrate is substantially thermally isolated from the second conductive substrate;
a plurality of primary connectors providing electrical contact between the N-type conductors in cold junctions and the N-type conductors in the hot junctions;
a plurality of secondary connectors providing electrical contact between the P-type conductors in cold junctions and the P-type conductors in the hot junctions; and
a plurality of tertiary connectors providing electrical contact between the thermoelectric device and a current source.

11. The thermoelectric device according to claim 10 wherein the primary connectors and the secondary connectors are configured and arranged to connect the cold junctions and the hot junctions in parallel.

12. The thermoelectric device according to claim 10 wherein the primary connectors and the secondary connectors are configured and arranged to connect the cold junctions and the hot junctions in parallel.

13. The thermoelectric device according to claim 10 wherein the primary connectors and the secondary connectors are configured and arranged to connect the cold junctions and the hot junctions in series and parallel.

14. A method of constructing a thermoelectric device comprising:
forming a plurality of cold plates, each cold plate comprising a cold junction and a first conductive substrate, the cold junction comprising an N-type conductor in contact with a P-type conductor, the cold junction being in thermal contact with the first conductive substrate;
forming a plurality of hot plate, the hot plate comprising a hot junction and a second conductive substrate, the hot junction comprising an N-type conductor in contact with a P-type conductor, the hot junction being in thermal contact with the second conductive substrate;
thermally isolating the cold plates from the hot plates, the thermal isolation being accomplished by one or more methods selected from the group consisting of separating the cold plates and the hot plates and using insulating materials to prevent heat transfer from the hot plates to the cold plates;
forming a plurality of primary connectors for providing electrical contact between the N-type conductors of the cold junctions and the N-type conductors of the hot junctions, the primary connectors being configured and arranged to provide a fin parameter of at least 5;
forming a plurality of secondary connectors for providing electrical contact between the P-type conductors of the cold junctions and the P-type conductors of the hot junctions, the secondary connectors being configured and arranged to provide a fin parameter of at least 5;
forming a cold connector that provides electric contact between at least one cold plate and a current source;
forming a hot connector that provides electrical contact between at least one hot plate and the current source; and
arranging the cold plates, hot plates, primary connectors, secondary connectors, cold connector, hot connector, and current source to form a complete circuit.

15. The method of constructing a thermoelectric device according to claim 14 wherein
each cold plate comprises a plurality of cold junctions and a first conductive substrate, each cold junction comprising an N-type conductor in contact with a P-type conductor, each of the cold junctions being in thermal contact with the first conductive substrate;
wherein each hot plate comprises a plurality of hot junctions and a second conductive substrate, each hot junction comprising an N-type conductor in contact with a P-type conductor, each of the hot junctions being in thermal contact with the second conductive substrate;
wherein each of the primary connectors and secondary connectors is substantially covered with an insulating material sufficient to prevent unintentional electrical contact between adjacent primary connectors and secondary connectors; and
wherein configuring the cold plates, hot plates, primary connectors, secondary connectors, cold connector, hot connector, and current source to form a complete circuit further comprises forming both parallel and series connections.
